(19) United States
(12) Patent Application Publication
(10) Pub. No.: US 2013/0069228 A1
(43) Pub. Date: Mar. 21, 2013

(54) FLIP-CHIP PACKAGE STRUCTURE AND FORMING METHOD THEREOF

(71) Applicants: An-Hong LIU, Hsinchu (TW); Hung-Hsin Liu, Hsinchu (TW); Jar-Dar Yang, Hsinchu (TW); Chi-Chia Huang, Hsinchu (TW); Yi-Chang Lee, Hsinchu (TW); Hsiang-Ming Huang, Hsinchu (TW)

(72) Inventors: An-Hong LIU, Hsinchu (TW); Hung-Hsin Liu, Hsinchu (TW); Jar-Dar Yang, Hsinchu (TW); Chi-Chia Huang, Hsinchu (TW); Yi-Chang Lee, Hsinchu (TW); Hsiang-Ming Huang, Hsinchu (TW)

(21) Appl. No.: 13/559,087

(22) Filed: Jul. 26, 2012

(30) Foreign Application Priority Data
Sep. 15, 2011 (TW) 100133133

(51) Int. Cl. H01L 23/498; H01L 21/60

(52) U.S. Cl. 257/737; 438/108; 257/E23.068; 257/E21.506

(57) ABSTRACT

A flip-chip package structure comprising a substrate, a chip, a bump structure and a solder resist is provided. The substrate has a circuit layer disposed on the surface thereof. The chip comprises a central region and two edge regions disposed on the two sides of the central region. The bump structure is disposed on the central region of the chip and faces the substrate. The solder resist is disposed on the substrate to partially cover the circuit layer. The chip is electrically connected to the substrate by the bump structure, and the solder resist is adapted to come into contact with the two edge regions of the chip to support the chip with the bump structure when the chip is disposed on the substrate.

This application claims priority to Taiwan Patent Application No. 100133133 filed on Sep. 15, 2011.

### CROSS-REFERENCES TO RELATED APPLICATIONS

Not applicable.

### BACKGROUND OF THE INVENTION

1. Field of the Invention

The present invention provides a semiconductor package structure, and in particular, a flip-chip package structure for use in semiconductor fields.

2. Descriptions of the Related Art

Flip-chip package structures have been widely applied in various kinds of electronic logic components because of their advantages, such as high pin density, high heat dissipation efficiency, and their small sizes. In particular, flip-chip package structures are widely used, for example, in central processing units (CPUs),graphics processing units (GPUs) commonly found in personal computers (PCs), or in network chips with both wireless and Bluetooth communication functions. A flip-chip package structure is mainly comprised of a substrate, a chip and bump structures for electrically connecting the substrate with the chip. When the bump structures are disposed between the substrate and the chip to support and electrically connect the substrate and the chip, a gap is formed between the substrate and the chip. Meanwhile, the gap is filled with a filler by means of a natural flowing process or the capillary phenomenon so that the chip and the substrate are fixed and insulated from each other and short-circuiting between the bump structures from contact therebetween are avoided.

However, due to the advancement of the manufacturing process technologies and the demands for miniaturized electronic components, the substrates and the chips become increasingly smaller in size while the number of required signal pins is still increasing. Consequently, this leads to a smaller gap between the substrate and the chip, which increases the difficulty in the manufacturing process. On the other hand, because a too small of a gap makes it difficult for the filler to flow and be filled therein smoothly, the oxidation of the circuit layer or short-circuits between the contacts may occur and negatively affect the service life of the flip-chip package structure.

Accordingly, it is important to provide a solution that can miniaturize the flip-chip package structure while still maintaining the size of the gap between the substrate and the chip so that the filler can be filled therebetween smoothly by means of the capillary phenomenon.

### SUMMARY OF THE INVENTION

An objective of the present invention is to provide a flip-chip package structure which, while allowing for the miniaturization of the substrate and the chip, can not only fix the chip to the substrate securely but also maintain the size of the gap therebetween so that a filler can be filled into the gap completely. Thereby, the chip and the substrate can be fixed and insulated from each other, and short-circuiting between the bump structures due to contact therebetween can be avoided.

To achieve the aforesaid objective, the present invention provides a flip-chip package structure, which comprises a substrate, a chip, a bump structure and a solder resist. The substrate has a circuit layer thereon. The chip comprises a central region and two edge regions disposed on two sides of the central region. The bump structure is disposed on the central region of the chip and faces the substrate. The solder resist is disposed on the substrate to partially cover the circuit layer. The chip is electrically connected to the substrate via the bump structure, and the solder resist is adapted to come into contact with the two edge regions of the chip to support the chip with the bump structure when the chip is disposed on the substrate.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1A is a schematic view of the first embodiment of a flip-chip package structure according to the present invention;

FIG. 1B is a cross-sectional view taken along line A-A of FIG. 1A;

FIG. 2A is a schematic view of the second embodiment of the flip-chip package structure according to the present invention;

FIG. 2B is a cross-sectional view taken along line B-B of FIG. 2A;

FIG. 3A is a schematic view of the third embodiment of the flip-chip package structure according to the present invention;

FIG. 3B is a cross-sectional view taken along line C-C of FIG. 3A;

FIG. 4A is a schematic view of the fourth embodiment of the flip-chip package structure according to the present invention;

FIG. 4B is a cross-sectional view taken along line D-D of FIG. 4A;

FIG. 5 is a flowchart diagram of the manufacturing process of the flip-chip package structure according to the present invention; and

FIG. 6 is another flowchart diagram of the manufacturing process of the flip-chip package structure according to the present invention.

### DESCRIPTION OF THE PREFERRED EMBODIMENT

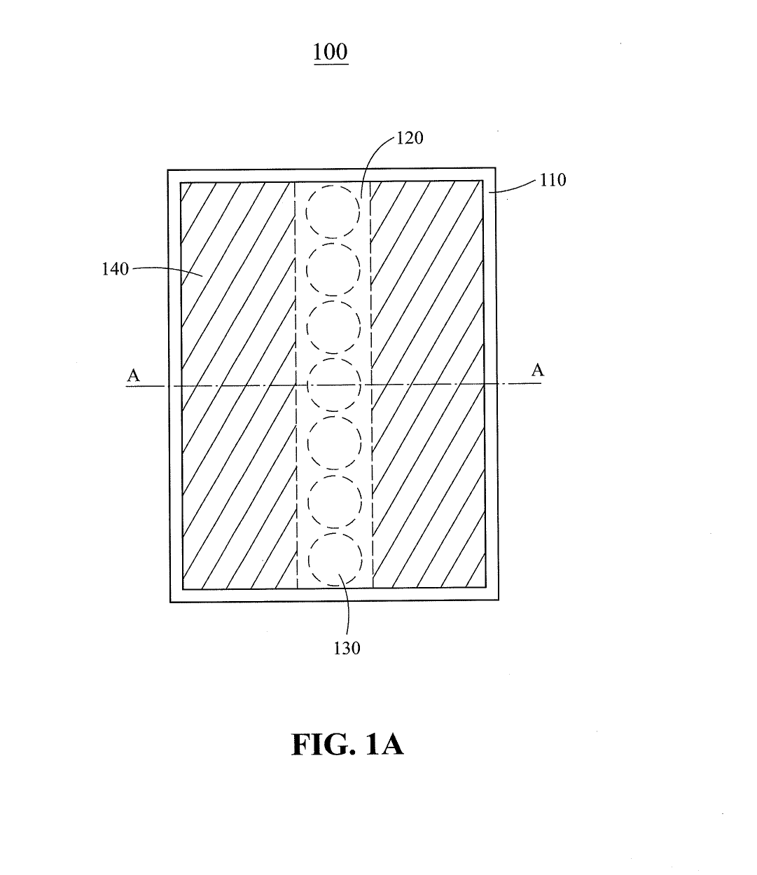

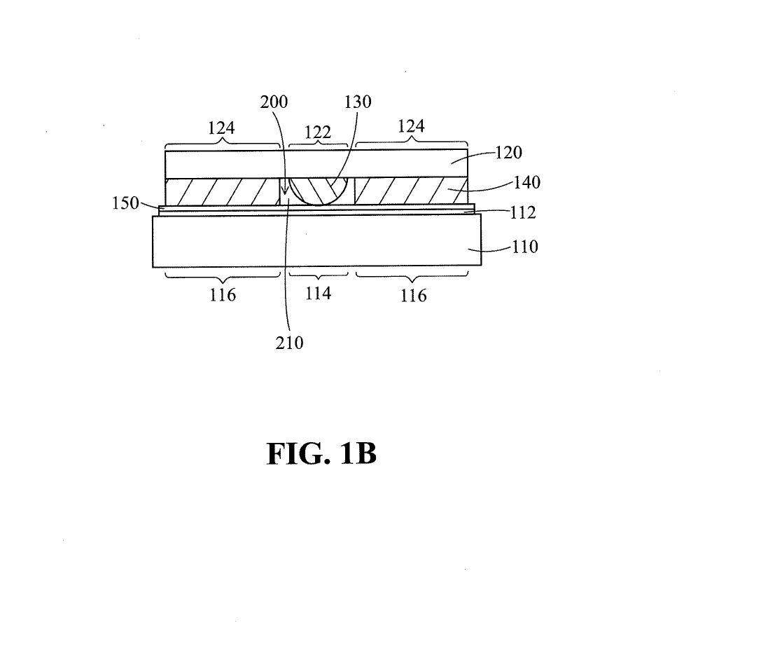

FIGS. 1A and 1B show a first embodiment of a flip-chip package structure 100 according to the present invention. As shown, the flip-chip package structure 100 comprises a substrate 110, a chip 120, a bump structure 130 and a solder resist 140. The substrate 110 has a circuit layer 112 (the circuit layer is shown only schematically here) thereon, and the chip 120 comprises a central region 122 and two edge regions 124 disposed on two sides of the central region 122. Furthermore, the bump structure 130 is disposed on the central region 122 of the chip 120 and faces toward the substrate 110. The solder resist 140 is disposed on the substrate 110 to partially cover the circuit layer 112. In this embodiment, the bump structure 130 is, for example, a gold bump, a stud bump or a composite bump.

As shown in FIG. 1B, when the chip 120 is disposed on the substrate 110, the chip 120 is adapted to electrically connect with the substrate 110 via the bump structure 130, and meanwhile, the solder resist 140 is adapted to come into contact with the two edge regions 124 of the chip 120 to support the chip 120 with the bump structure 130. Thus, the inclination of the chip 120 to the left or to the right when only the central region 122 of the chip 120 is supported can be avoided.

The flip-chip package structure 100 further comprises an anti-oxidation layer 150, which covers the circuit layer 112 of the substrate 110 to assist in avoiding oxidation of the circuit layer 112. The anti-oxidation layer 150 is formed of a nickel-gold material or a nickel-palladium-gold material. Furthermore, when the solder resist 140 cooperates with the bump structure 130 to support the chip 120, a gap 200 is formed between the substrate 110 and the chip 120. A filling layer 210 is adapted to be filled in the gap 200 as an insulation material between the substrate 110 and the chip 120 to, on one hand, avoid short-circuiting therebetween and, on the other hand, fix the substrate 110 and the chip 120.

It shall be appreciated that as shown in FIG. 1A, the solder resist 140 in the first embodiment of the present invention is disposed on the substrate 110 in such a way that the solder resist 140 covers three quarters of the area of the substrate 110 from two sides 116 toward the central portion 114 of the substrate 110 to support the chip 120 with the bump structure 130 Therefore, because there is still a sufficient gap 200 left between the substrate 110 and the chip 120, the filler (not shown) to be filled in the gap 200 can smoothly flow into the gap 200 without being blocked to form the filling layer 210. When the package structure has an area of 8 mm (width)*11.5 mm (length) and the solder resist 140 covers three quarters of the area, the space, with a width of 2 mm, is left in the central portion 114 with the widths of the two sides 116 being about 3 mm respectively.

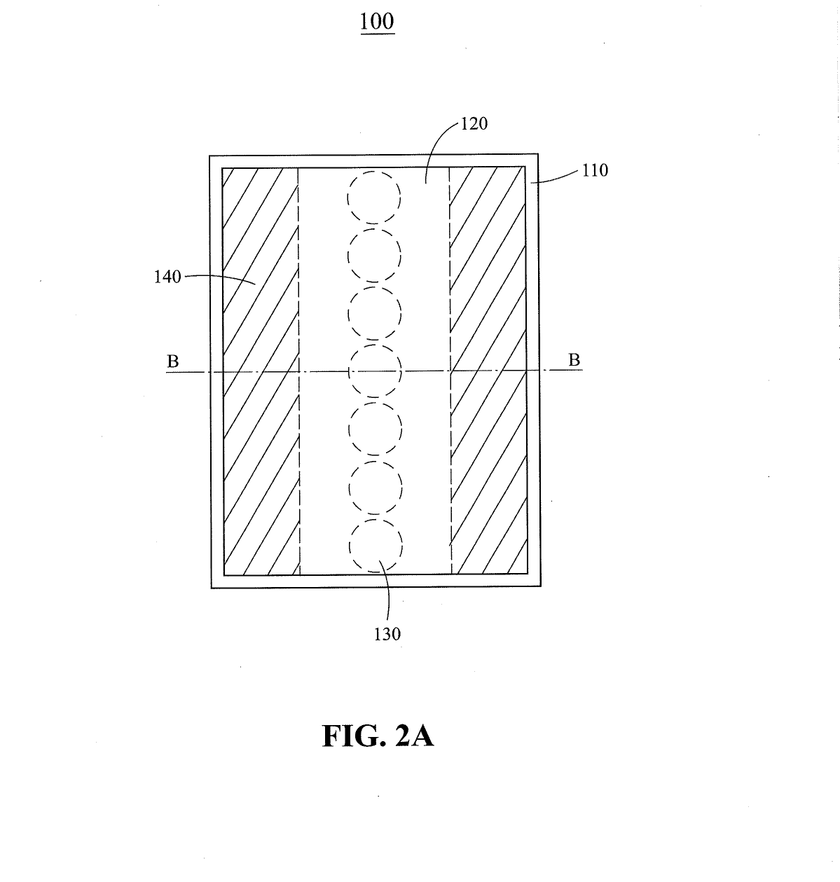

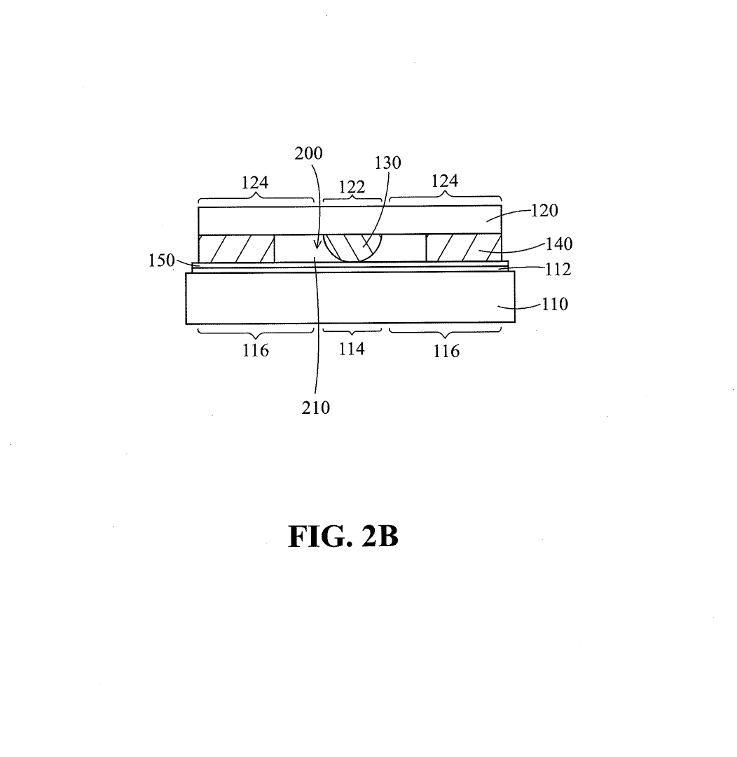

FIGS. 2A and 2B show a second embodiment of the present invention. As shown, a spatial relationships between the substrate 110, the chip 120, the bump structure 130 and the solder resist 140 comprised in the flip-chip package structure 100 according to the second embodiment are the same as the first embodiment only except that the solder resist 140 shown in the second embodiment is disposed on the substrate 110 in such a way that the solder resist 140 covers half the area of the substrate 110 from the two sides 116 toward the central portion 114 of the substrate 110 to support the chip 120 with the bump structure 130. Therefore, as compared with the first embodiment, the flip-chip package structure 100 shown in the second embodiment can cooperate with the bump structure 130 to support the chip 120 by using less solder resist 140. This can avoid the inclination of the chip 120 to the left or to the right and, meanwhile, still allow the filler to smoothly flow into the gap 200 to be filled therein through portions uncovered by the solder resist 140.

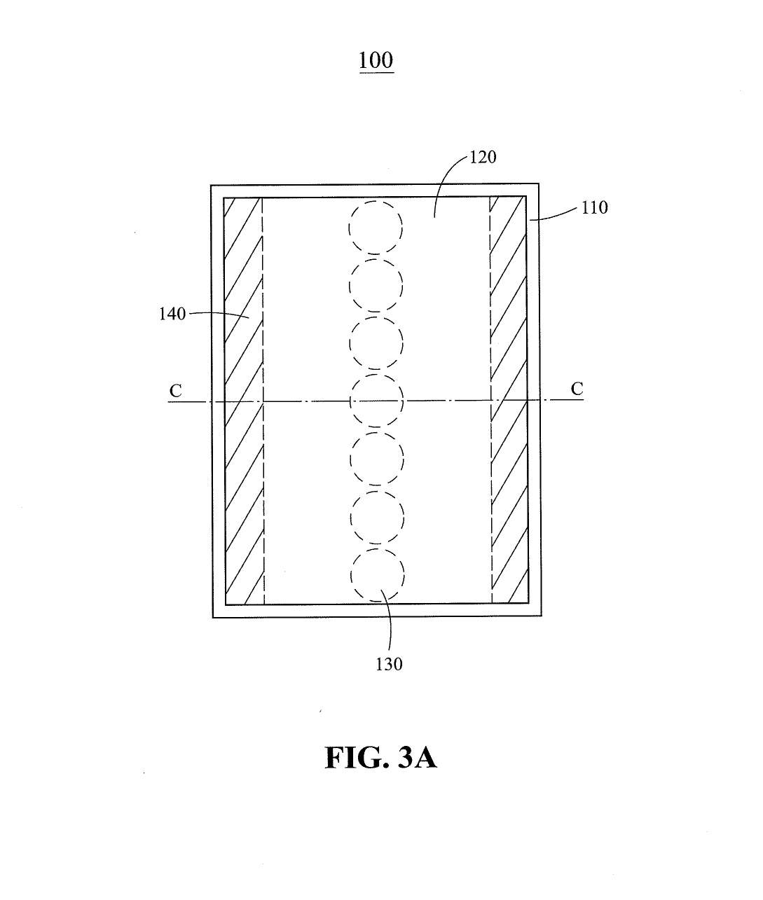

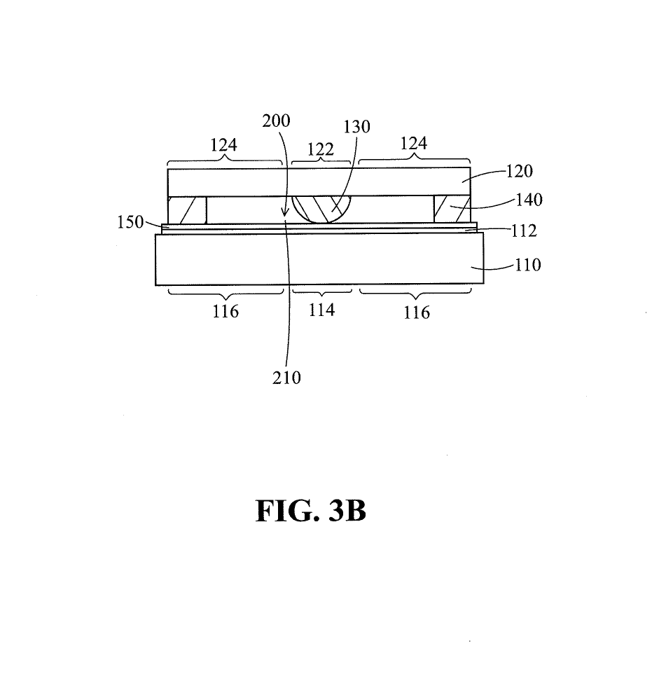

FIGS. 3A and 3B show a third embodiment of the present invention. As shown, the spatial relationships between the substrate 110, the chip 120, the bump structure 130 and the solder resist 140 comprised in the flip-chip package structure 100 according to the third embodiment are the same as the first and the second embodiments only except that the solder resist 140 shown in the third embodiment is disposed on the substrate 110 in such a way that the solder resist 140 covers one quarter of the area of the substrate 110 from the two sides 116 towards the central portion 114 of the substrate 110 to support the chip 120 with the bump structure 130. Therefore, as compared with the first and the second embodiments, the flip-chip package structure 100 shown in the third embodiment supports the chip 120 with the bump structure 130 by using less solder resist 140. This can avoid the inclination of the chip 120 to the left or to the right and enable the filler to flow into the gap 200 more smoothly.

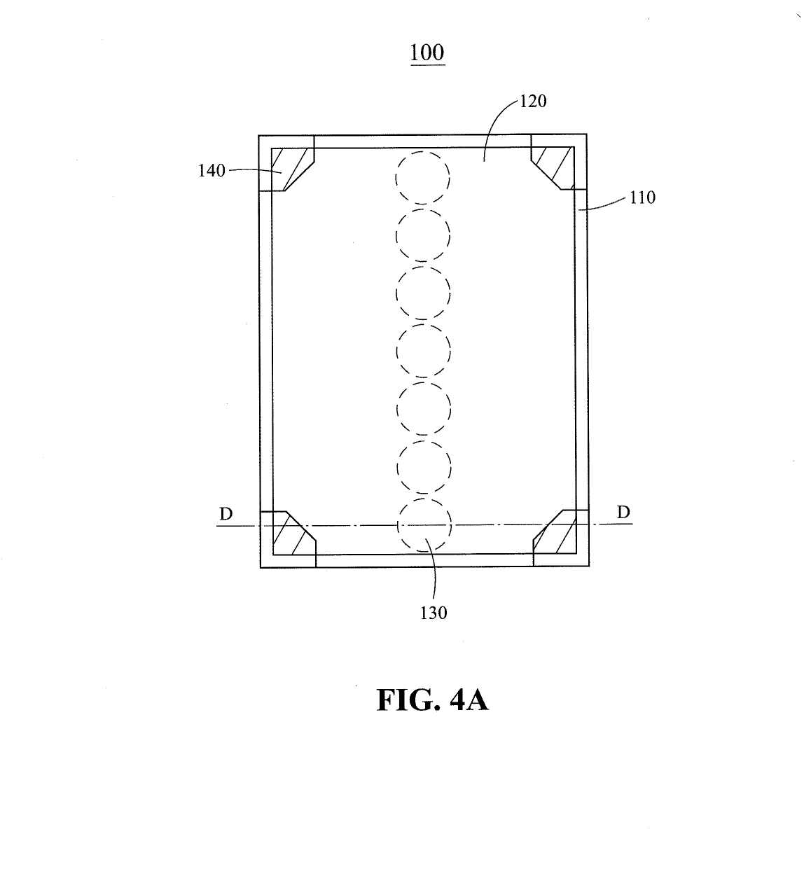

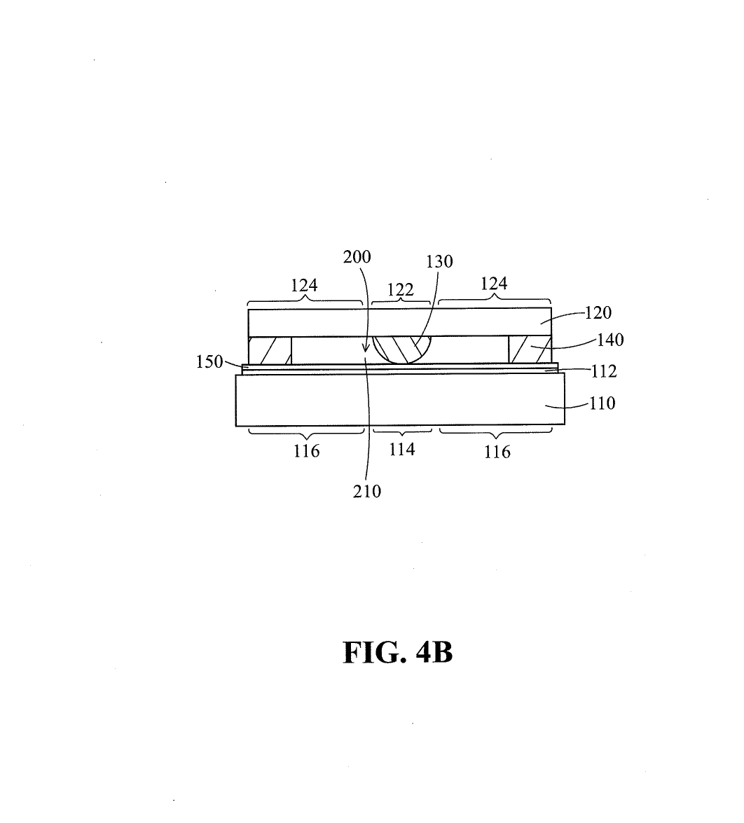

FIGS. 4A and 4B show a fourth embodiment of the present invention. As shown, although the spatial relationships between the substrate 110, the chip 120 and the bump structure 130 comprised in the flip-chip package structure 100 according to the fourth embodiment are the same as the aforesaid embodiments, the solder resist 140 in this embodiment covers the substrate 110 that are not from the two sides 116 and are instead towards the central portion 114 of the substrate 110. Instead, the solder resist 140 according to the fourth embodiment is disposed on the four corners of the substrate 110 to support the chip 120 with the bump structure 130. Thus, a bigger gap 400 can be formed between the substrate 110 and the chip 120 for the filler to flow and be filled therein.

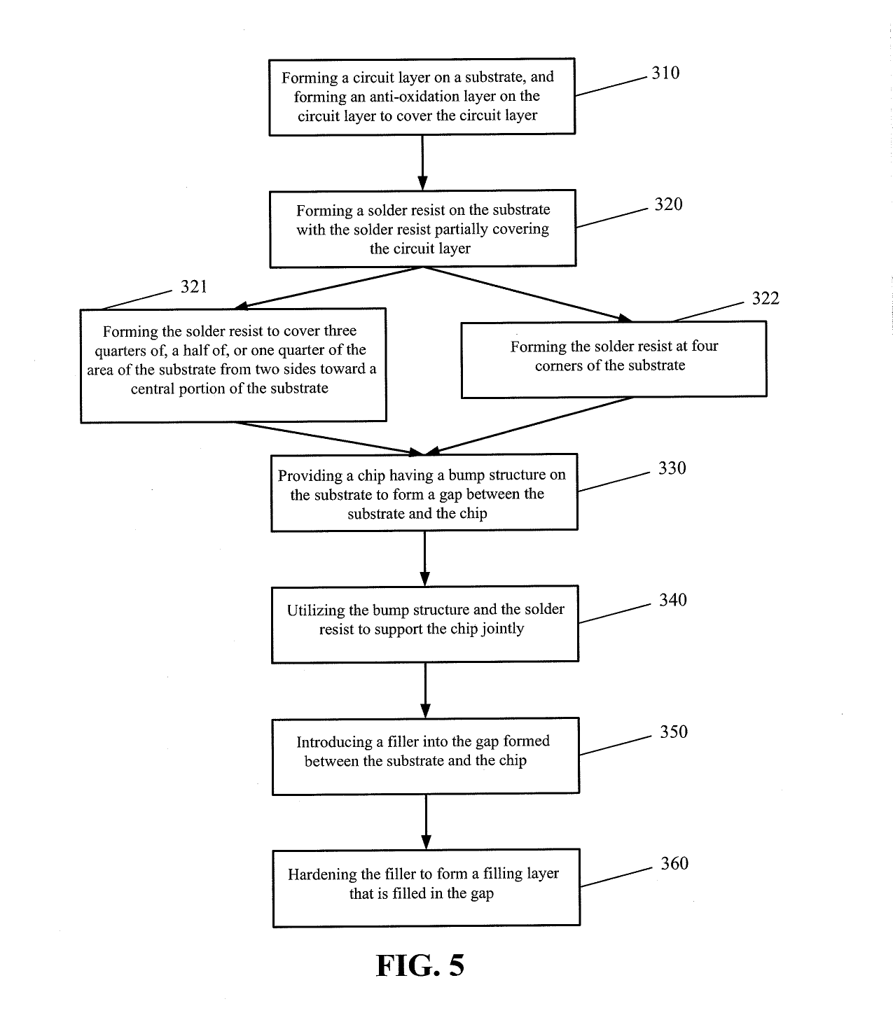

The present invention further provides a method for forming the aforesaid flip-chip package structure 100, which comprises the following steps as shown in FIG. 5. First, as shown in step 310, a circuit layer 112 is formed on a substrate 100, and an anti-oxidation layer 150 is formed on the circuit layer 112 to cover and protect the circuit layer 112. Then, as shown in step 320, a solder resist 140 is formed on the substrate 110 with the solder resist 140 only partially covering the circuit layer 112. As shown in step 330, a chip 120 with a bump structure 130 is provided on the substrate 110 to form a gap 200 between the substrate 110 and the chip 120. As shown in step 340, the bump structure 130 and the solder resist 140 are used to jointly support the chip 120. Subsequently, as shown in step 350, a filler is introduced into the gap 200 formed between the substrate 110 and the chip 120. Finally, as shown in step 360, the filler is hardened to form a filling layer 210 that is filled in the gap 200. The filling layer 210 can enhance the firmness of the attachment between the substrate 110 and the chip 120, and meanwhile, avoid short-circuiting between the substrate 110, the chip 120 and the bump structure 130 due to poor insulation therebetween.

Furthermore, the step 320 of forming the solder resist 140 may further comprise step 321, which comprises the formation of the solder resist 140 to cover three quarters of the area of the substrate 110, a half of the area of the substrate 110, or one quarter of the area of the substrate 110 from the two sides 116 and towards a central portion 114 of the substrate 110 to support the chip 120 with the bump structure 130. Alternatively, the step 320 may also further comprise step 322, which compromises the formation of the solder resist 140 at the four corners of the substrate 110 to support the chip 120 with the bump structure 130.

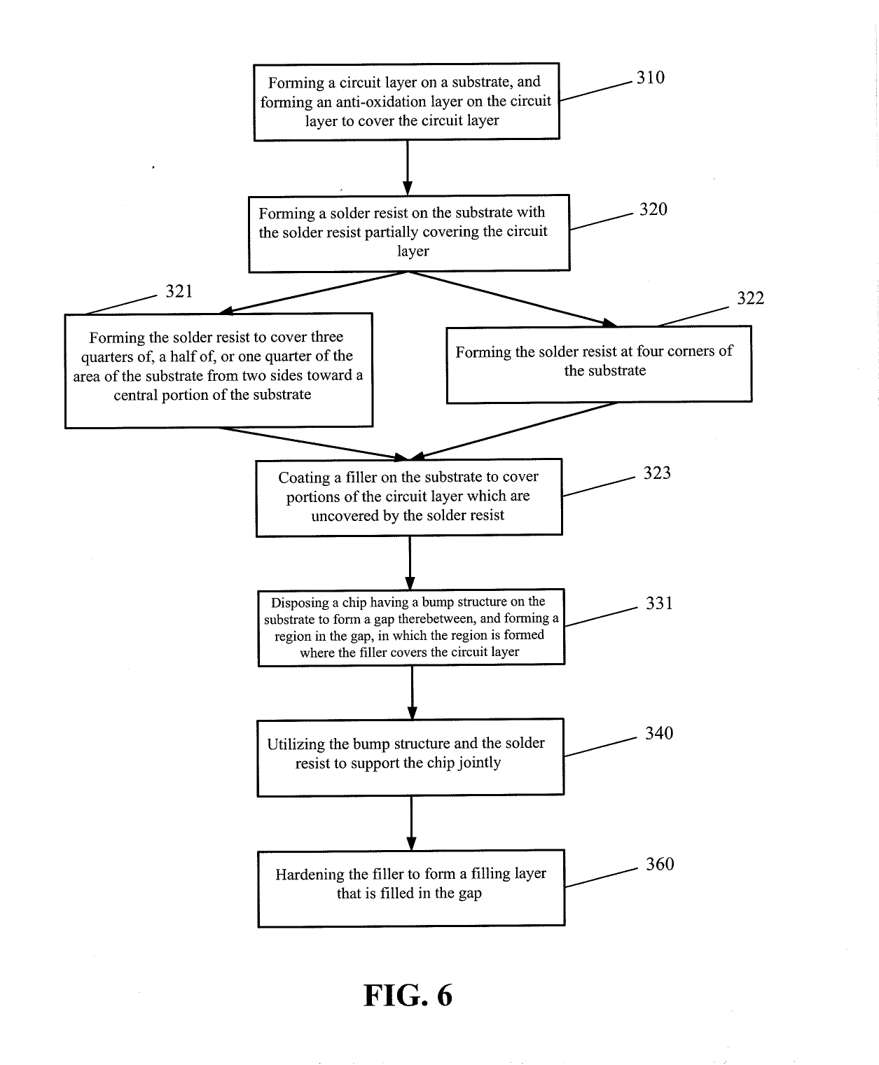

As shown in FIG. 6, the aforesaid method for forming the flip-chip package structure 100 may also comprise the following steps after step 321 or step 322 of forming the solder resist 140. First, as shown in step 323, a filler is coated on the substrate 110 to cover the portions of the circuit layer 112 which are uncovered by the solder resist 140. Then, as shown in step 331, a chip 120 with a bump structure 130 is provided on the substrate 110 with a gap 200 being formed between the chip 120 and the substrate 110. As shown in step 340, the bump structure 130 and the solder resist 140 are utilized to jointly support the chip 120. The excessive filler can flow out through a region uncovered by the solder resist 140. Finally, as shown in step 360, the filler is hardened to form a filling layer 210 that is filled in the gap 200.

In the present invention, the bump structure 130 is preferably a gold stud bump and is disposed on the central region 122 of the chip 120 in the form of a single matrix or a plurality of matrices and facing toward the substrate 110. Furthermore, the height of the gap 200 formed between the substrate 110 and the chip 120 is between 20 and 50 microns, and preferably is 30 microns. The thickness of the solder resist 140 may be between 5 and 20 microns, and preferably, 15 microns. In this way, a commonly used filler can smoothly flow into the gap without the need of using a special filler, thereby reducing the production cost.

It shall be appreciated that the filler mentioned in step 350 described in FIG. 5 may be an underfill or a molding material filler; and the filler may be allowed to flow into and be filled in the gap 200 after the gap 200 is formed to achieve the purposes of avoiding short-circuiting and fixing the substrate 110 and the chip 120 in the present invention. On the other hand, the filler mentioned in the step 323 described in FIG. 6 is a non-conductive paste (NCP); and the filler must be firstly coated on portions of the circuit layer 112 uncovered by the solder resist 140 before subsequent operations of disposing the substrate 110 and the chip 120 are carried out, and then the excessive filler can smoothly flow out through regions on the substrate 110 which are uncovered by the solder resist 140.

According to the above descriptions, because the flip-chip package structure 100 of the present invention can maintain the height of the gap 200 between the substrate 100 and the chip 120 through the disposition of the bump structure 130 and the solder resist 140, the operation of filling the filler into the gap 200 can still be accomplished to form the filling layer 210 without changing the original kind of filler. Thereby, the chip 120 and the substrate 110 can be insulated from each other, and short-circuiting between bump structures 130 due to contact therebetween can be avoided.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

1. A flip-chip package structure, comprising:
a substrate, with a circuit layer formed on the substrate;
a chip, having a central region and two edge regions disposed at two sides of the central region;
a bump structure, being disposed on the central region of the chip and facing toward the substrate; and
a solder resist, being disposed on the substrate and partially covering the circuit layer;
wherein the chip is electrically connected to the substrate via the bump structure, and the solder resist is adapted to contact with the two edge regions of the chip so as to cooperate with the bump structure to support the chip when the chip is disposed on the substrate.

2. The flip-chip package structure as claimed in claim 1, wherein the solder resist is disposed on the substrate in such a way that the solder resist covers three quarters of the area of the substrate, a half of the area of the substrate, or one quarter of the area of the substrate from two sides toward a central portion of the substrate so as to cooperate with the bump structure to support the chip.

3. The flip-chip package structure as claimed in claim 1, wherein the solder resist is disposed at four corners of the substrate so as to cooperate with the bump structure to support the chip.

4. The flip-chip package structure as claimed in claim 1, further comprising an anti-oxidation layer covering the circuit layer of the substrate.

5. The flip-chip package structure as claimed in claim 1, further comprising a gap and a filling layer, the gap is formed between the substrate and the chip, and the filling layer is filled in the gap.

6. The flip-chip package structure as claimed in claim 5, wherein the gap has a height which is between 20 and 50 microns.

7. A method for forming a flip-chip package structure, comprising the following steps:
(a) forming a circuit layer on a substrate, and forming an anti-oxidation layer on the circuit layer for covering the circuit layer;
(b) forming a solder resist on the substrate, with the solder resist partially covering the circuit layer;
(c) providing a chip with a bump structure on the substrate, and forming a gap between the substrate and the chip, wherein the chip has a central region and two edge regions disposed at two sides of the central region, and the areas of the two edge regions of the chip make partial contact with the solder resist; and
(d) utilizing the bump structure and the solder resist to support the chip jointly.

8. The method as claimed in claim 7, wherein the step (b) further comprises:
(b1) forming the solder resist to cover three quarters of the area of the substrate, a half of the area of the substrate, or one quarter of the area of the substrate from two sides toward a central portion of the substrate so as to cooperate with the bump structure to support the chip.

9. The method as claimed in claim 7, wherein the step (b) further comprises:
(b2) forming the solder resist at four corners of the substrate so as to cooperate with the bump structure to support the chip.

10. The method as claimed in claim 7, further comprising the following steps:
(e) providing a filler into the gap which is formed between the substrate and the chip; and
(f) hardening the filler to form a filling layer that is filled in the gap.

11. The method as claimed in claim 8, further comprising the following step:
(b3) coating a filler on the substrate to cover portions of the circuit layer which are uncovered by the solder resist.

12. The method as claimed in claim 11, further comprising the following steps:
(g) forming a region in the gap, in which the region is formed where the filler covers the circuit layer.
hardening the filler to form a fill layer that is filled in the gap.

13. The method as claimed in claim 9, further comprising the following step:
(b3) coating a filler on the substrate to cover portions of the circuit layer which are uncovered by the solder resist.

14. The method as claimed in claim 13, further comprising the following steps:
(g) forming a region in the gap, in which the region is formed where the filler covers the circuit layer.
hardening the filler to form a fill layer that is filled in the gap.
